(19) United States
(12) Patent Application Publication
(10) Pub. No.: US 2024/0203809 A1
(43) Pub. Date: Jun. 20, 2024

(54) ELECTRONIC DEVICE INCLUDING RIGID DIELECTRIC LID AND OVERLAYING THERMOSET POLYMER LAYER AND RELATED METHODS

(71) Applicant: EAGLE TECHNOLOGY. LLC, Melbourne, FL (US)

(72) Inventors: Louis R. PARADISO, Satellite Beach, FL (US); Douglas R. HEILMAN, Palm Bay, FL (US)

(21) Appl. No.: 18/085,173

(22) Filed: Dec. 20, 2022

(51) Int. Cl. H01L 23/31; H01L 21/52; H01L 21/56; H01L 23/00; H01L 23/053; H01L 23/20

(52) U.S. Cl. CPC H01L 23/3121; H01L 21/52; H01L 21/56; H01L 23/053; H01L 23/20; H01L 24/48; H01L 23/10

(57) ABSTRACT

An electronic device may include a dielectric substrate and bond wire pads on an upper surface thereof. The electronic device may also include a radio frequency (RF) integrated circuit (IC) mounted to the upper surface of the dielectric substrate and bond wires coupling the RF IC to respective bond wire pads. The electronic device may also include a rigid dielectric lid mounted to the upper surface of the dielectric substrate to define an air cavity above the RF IC and the bond wires, and a thermosetting polymer layer over the rigid dielectric lid.

### TECHNICAL FIELD

The present invention relates to the field of electronics, and, more particularly, to electronic device packaging and related methods.

### BACKGROUND

An electronic device may be chosen for desirable electrical characteristics. For example, a given electronic device may be chosen for desired gain in a desired frequency range, which may correspond to the desired use (e.g., terrestrial, aerospace, avionic). The electronic device may also be chosen to include packaging or coupling to accommodate environmental conditions for the desired use. For example, an electronic device to be used in outer space may be subject to certain environmental factors not necessarily found in terrestrial applications.

However, there may often be a tradeoff between performance and meeting or exceeding environmental guidelines for a particular application. For example, a given electronic device may be packaged to meet environmental guidelines for aerospace use, but the gain or other electrical performance may be undesirable.

### SUMMARY

An electronic device may include a dielectric substrate and a plurality of bond wire pads on an upper surface thereof. The electronic device may also include a radio frequency (RF) integrated circuit (IC) mounted to the upper surface of the dielectric substrate, and a plurality of bond wires coupling the RF IC to respective bond wire pads. The electronic device may also include a rigid dielectric lid mounted to the upper surface of the dielectric substrate to define an air cavity above the RF IC and the plurality of bond wires, and a thermosetting polymer layer over the rigid dielectric lid.

The RF IC may include a Monolithic Microwave Integrated Circuit (MMIC), for example. The rigid dielectric lid may have a melting temperature above a curing temperature of the thermoset polymer layer, for example. The rigid dielectric lid may include a top and a plurality of sidewalls depending therefrom.

The plurality of bond wire pads may be spaced inwardly from a perimeter of the dielectric substrate and outwardly from the RF IC, for example. The thermoset polymer layer may have a conformal shape with the rigid dielectric lid.

The thermoset polymer layer and the rigid dielectric lid may define a near hermetic seal with the dielectric substrate. The electronic device may also include an adhesive securing the rigid dielectric lid to the upper surface of the dielectric substrate, for example.

A method aspect is directed to a method for making an electronic device. The method may include mounting a radio frequency (RF) integrated circuit (IC) to an upper surface of a dielectric substrate having a plurality of bond wire pads on the upper surface thereof, and coupling a plurality of bond wires between the RF IC and respective bond wire pads. The method may also include mounting a rigid dielectric lid to the upper surface of the dielectric substrate to define an air cavity above the RF IC and the plurality of bond wires, and curing a thermoset polymer layer over the rigid dielectric lid.

### BRIEF DESCRIPTION OF THE DRAWINGS

FIG. 1 is a schematic diagram of an electronic device in accordance with an embodiment.

FIG. 2 is a schematic cross-sectional side view of the electronic device of FIG. 1.

FIG. 3 is a schematic cross-sectional top view of the electronic device of FIG. 1.

FIG. 4 is a graph of simulated gain versus frequency of electronic devices with and without an air gap.

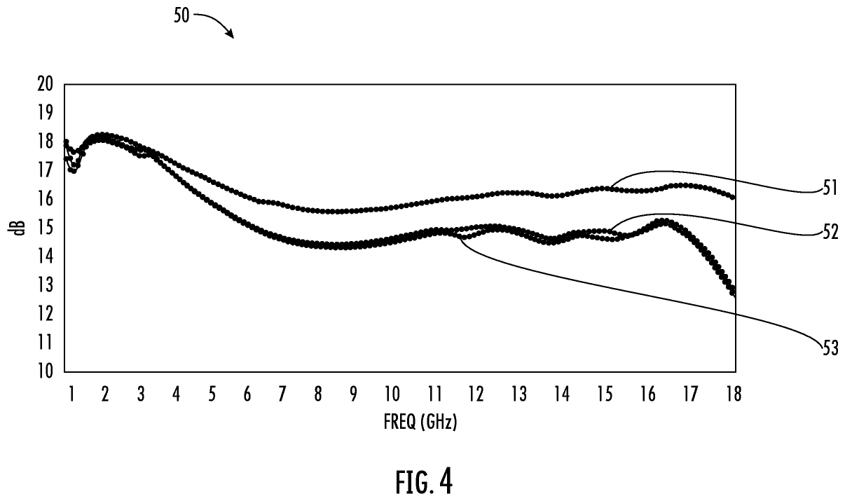

FIG. 5 is a graph of simulated gain versus frequency of an electronic device in accordance with an embodiment and an electronic device without a thermoset polymer layer.

FIG. 6 is a flow diagram illustrating a method of making an electronic device in accordance with an embodiment.

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

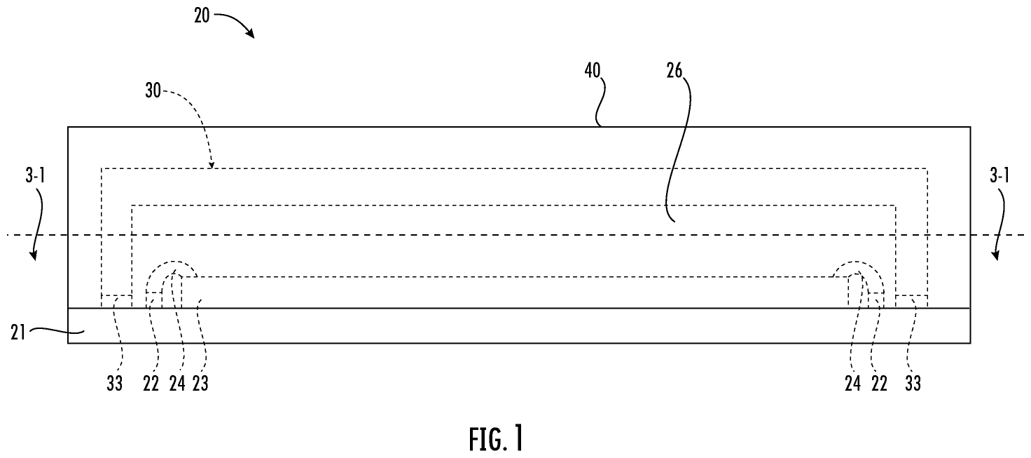

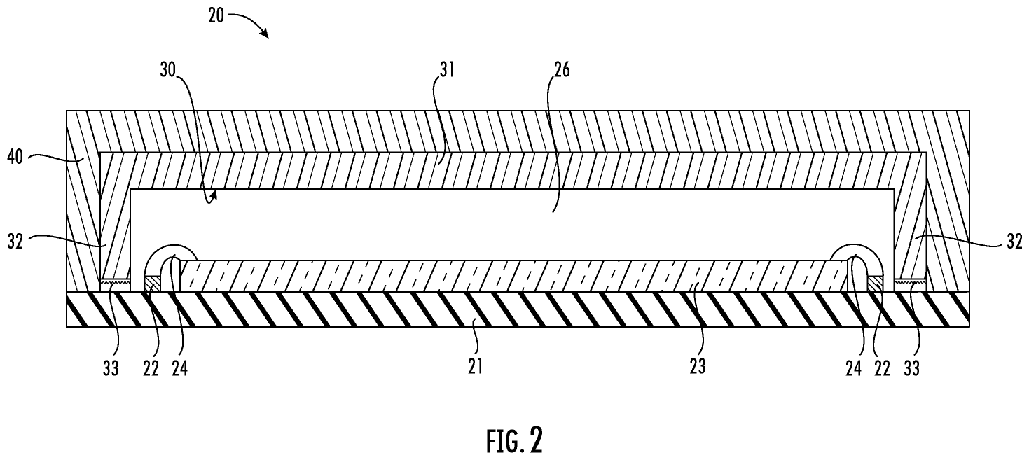

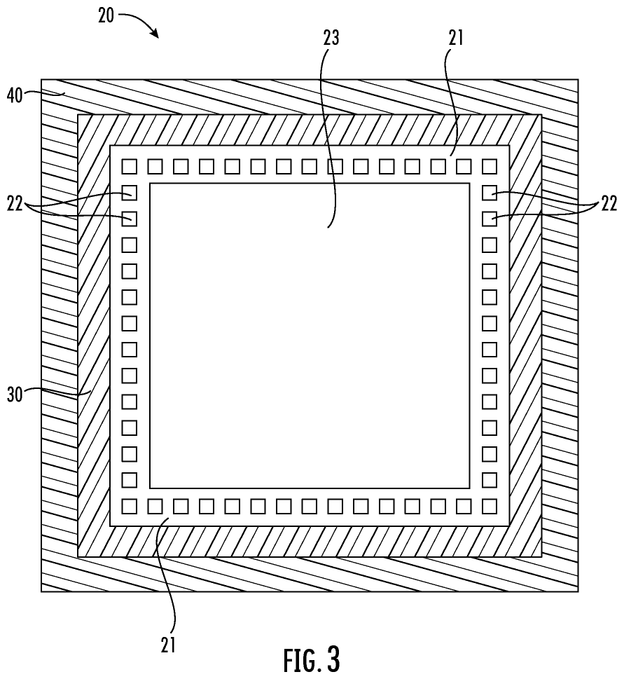

Referring initially to FIGS. 1-3, an electronic device 20 illustratively includes a dielectric substrate 21. The dielectric substrate 21 may include one or more laminated layers and/or pre-preg material. Electrical connection paths in the form of conductive traces and/or vias (not shown) may also be included within the dielectric substrate 21.

The electronic device 20 also illustratively includes a radio frequency (RF) integrated circuit (IC) 23 that is mounted to the upper surface of the dielectric substrate 21. The RF IC 23 may be a monolithic microwave integrated circuit (MMIC), for example. As will appreciated by those skilled in the art, the MMIC 23 may operate at microwave frequencies between 300 MHz and 40 GHz and may be used for functions, such as, for example, microwave mixing, power amplification, low-noise amplification, and high-frequency switching. Of course, the RF IC 23 may be another type of RF IC in other embodiments, as will be appreciated by those skilled in the art.

Bond wire pads 22 are on an upper surface of the dielectric substrate 21. The bond wire pads 22 are illustratively spaced inwardly from a perimeter of the dielectric substrate 21 and outwardly from the RF IC 23. As will be appreciated by those skilled in the art, in a typical bond wire pad footprint, the bond wire pads extend up to the perimeter edge of the dielectric substrate 21. However, in the present embodiments, the bond wire pads 22 are spaced inwardly from the perimeter edge, for example, by about 1 mm. In other words, in an exemplary implementation, there is about 1 mm of space between the perimeter edge of the dielectric substrate 21 and the bond wire pads 22. Bond wires 24 couple the RF IC 23 to respective bond wire pads 22.

A rigid dielectric lid 30 is mounted to the upper surface of the dielectric substrate 21 to define an air cavity 26 above the RF IC 23 and the bond wires 24. The rigid dielectric lids 30 illustratively includes a top 31 and sidewalls 32 depending or extending downwardly therefrom. The rigid dielectric lid 30 may have an exemplary thickness of 2 mm, for example.

The sidewalls 32 may be coupled to the upper surface of the dielectric substrate 21 by way of an adhesive 33, for example. An exemplary adhesive 33 may be Loctite® 3621 epoxy adhesive available from Henkel Corporation of Rocky Hill, Connecticut. The adhesive 33 may be another type of adhesive. The rigid dielectric lid 30 may include liquid crystal polymer (LCP).

A thermoset polymer layer 40 is over the rigid dielectric lid 30. The thermoset polymer layer 40 has a conformal shape with the rigid dielectric lid 30 and may individually or collectively define a near hermetic seal, for example, with the dielectric substrate 21. The thermoset polymer layer 40 may be G770H-FE available from Sumitomo Bakelite Co., LTD of Tokyo, Japan. Of course, the thermoset polymer layer 40 may include other and/or additional materials.

The rigid dielectric lid 30 may have a melting temperature above a curing temperature of the thermoset polymer layer 40. For example, during fabrication of the electronic device 20, the thermoset polymer layer 40 is cured over the rigid dielectric lid 30. Thus, it may be desirable to have the rigid dielectric lid 30 be able to withstand the relatively high temperatures of the thermoset polymer layer 40 as it cures.

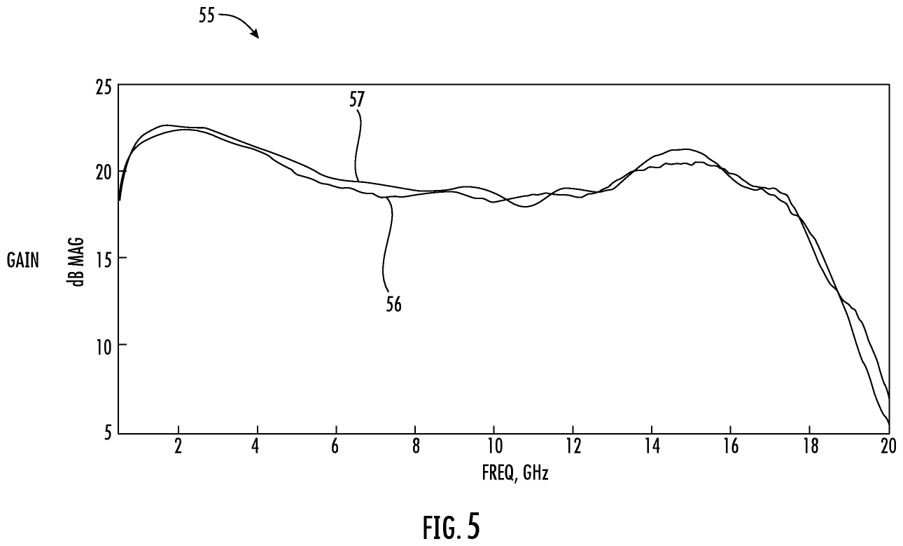

Referring now briefly to the graph 50 in FIG. 5, simulated gain versus frequency plots for electronic devices with and without an air cavity are illustrated. The line 51 corresponds to an electronic device with an air cavity 26, while lines 52 and 53 correspond to electronic devices without an air cavity. Illustratively, RF performance of electronic devices without an air cavity deteriorates above 5 GHz, for example.

Referring now to the graph 55 in FIG. 5, simulated gain versus frequency plots for electronic devices with and without the thermoset polymer layer 40 are illustrated. The line 56 corresponds to an electronic device having an air gap without the thermoset polymer layer 40, while the line 57 corresponds to an electronic device 20 having a thermoset polymer layer 40. Illustratively, the electronic device 20 with the thermoset polymer layer 40 provides a similar gain across a relatively wide range of frequencies, for example, the operational range of the MMIC 23, and the overall height of the electronic device may remain relatively the same.

Those skilled in the art will appreciate that a lid, for example, a dome lid or a thermosetting layer, in contact with an RF IC may cause undesirable parasitic effects. Metallic lids may also cause undesirable interference. And while a most desirable package or lid with respect to performance may be no package at all (i.e., no lid), an electronic device without an outer package may be subject to environmental conditions, and where relatively harsh environmental conditions exist, the absence of a package may make the electronic device unsatisfactory for its intended use. Accordingly, the embodiments of the electronic device 20 may advantageously provide increased electrical performance characteristics, for example, gain, across a relatively wide frequency range, and with desired environmental properties (e.g., to meet or exceed certain standards or requirements for avionics and space-based applications).

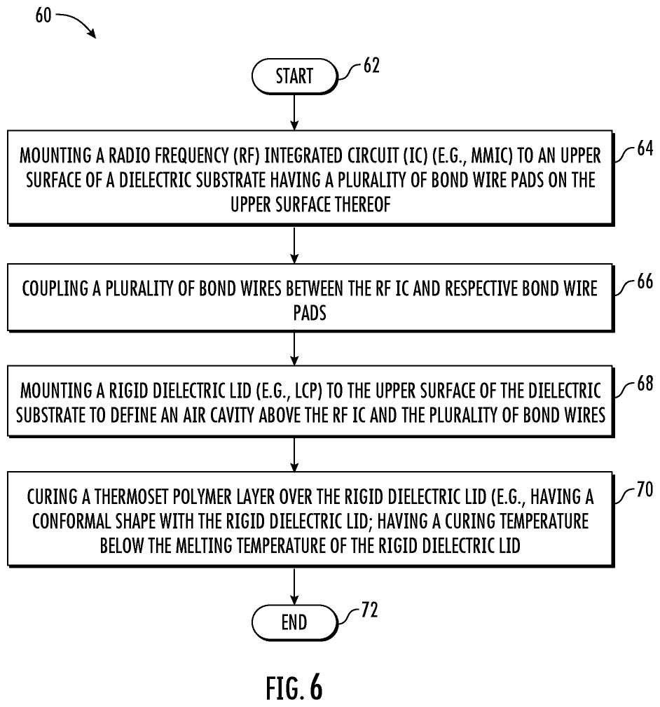

Referring now to the flowchart 60 in FIG. 6, beginning at Block 62, a method aspect is directed to a method for making an electronic device 20. The method includes mounting a radio frequency (RF) integrated circuit (IC) 23 to an upper surface of a dielectric substrate 21 having a plurality of bond wire pads 22 on the upper surface thereof (Block 64), and coupling a plurality of bond wires 24 between the RF IC and respective bond wire pads (Block 66). The method also includes mounting a rigid dielectric lid 30 to the upper surface of the dielectric substrate 21 to define an air cavity 26 above the RF IC 23 and the plurality of bond wires 24 (Block 68), and curing a thermoset polymer layer 40 over the rigid dielectric lid (Block 70). The method ends at Block 72.

While several embodiments have been described herein, it should be appreciated by those skilled in the art that any element or elements from one or more embodiments may be used with any other element or elements from any other embodiment or embodiments. Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. An electronic device comprising:
a dielectric substrate and a plurality of bond wire pads on an upper surface thereof;
a radio frequency (RF) integrated circuit (IC) mounted to the upper surface of the dielectric substrate;
a plurality of bond wires coupling the RF IC to respective bond wire pads;
a rigid dielectric lid mounted to the upper surface of the dielectric substrate to define an air cavity above the RF IC and the plurality of bond wires; and
a thermoset polymer layer over the rigid dielectric lid.

2. The electronic device of claim 1 wherein the RF IC comprises a Monolithic Microwave Integrated Circuit (MMIC).

3. The electronic device of claim 1 wherein the rigid dielectric lid has a melting temperature above a curing temperature of the thermoset polymer layer.

4. The electronic device of claim 1 wherein the rigid dielectric lid comprises a top and a plurality of sidewalls depending therefrom.

5. The electronic device of claim 1 wherein the plurality of bond wire pads are spaced inwardly from a perimeter of the dielectric substrate and outwardly from the RF IC.

6. The electronic device of claim 1 wherein the thermoset polymer layer has a conformal shape with the rigid dielectric lid.

7. The electronic device of claim 1 wherein the thermoset polymer layer and the rigid dielectric lid define a near hermetic seal with the dielectric substrate.

8. The electronic device of claim 1 further comprising an adhesive securing the rigid dielectric lid to the upper surface of the dielectric substrate.

9. An electronic device comprising:
a dielectric substrate and a plurality of bond wire pads on an upper surface thereof;
a Monolithic Microwave Integrated Circuit (MMIC) mounted to the upper surface of the dielectric substrate;
a plurality of bond wires coupling the MMIC to respective bond wire pads;
a rigid dielectric lid mounted to the upper surface of the dielectric substrate to define an air cavity above the RF IC and the plurality of bond wires;
an adhesive securing the rigid dielectric lid to the upper surface of the dielectric substrate; and
a thermoset polymer layer over the rigid dielectric lid.

10. The electronic device of claim 9 wherein the rigid dielectric lid has a melting temperature above a curing temperature of the thermoset polymer layer.

11. The electronic device of claim 9 wherein the rigid dielectric lid comprises a top and a plurality of sidewalls depending therefrom.

12. The electronic device of claim 9 wherein the plurality of bond wire pads are spaced inwardly from a perimeter of the dielectric substrate and outwardly from the MMIC.

13. The electronic device of claim 9 wherein the thermoset polymer layer has a conformal shape with the rigid dielectric lid.

14. The electronic device of claim 9 wherein the thermoset polymer layer and the rigid dielectric lid define a near hermetic seal with the dielectric substrate.

15. A method for making an electronic device comprising:
mounting a radio frequency (RF) integrated circuit (IC) to an upper surface of a dielectric substrate having a plurality of bond wire pads on the upper surface thereof;
coupling a plurality of bond wires between the RF IC and respective bond wire pads;
mounting a rigid dielectric lid to the upper surface of the dielectric substrate to define an air cavity above the RF IC and the plurality of bond wires; and
curing a thermoset polymer layer over the rigid dielectric lid.

16. The method of claim 15 wherein the RF IC comprises a Monolithic Microwave Integrated Circuit (MMIC).

17. The method of claim 15 wherein the rigid dielectric lid has a melting temperature above a curing temperature of the thermoset polymer layer.

18. The method of claim 15 wherein the rigid dielectric lid comprises a top and a plurality of sidewalls depending therefrom.

19. The method of claim 15 wherein the plurality of bond wire pads are spaced inwardly from a perimeter of the dielectric substrate and outwardly from the RF IC.

20. The method of claim 15 wherein the thermoset polymer layer and the rigid dielectric lid define a near hermetic seal with the dielectric substrate.
